(19) United States
(12) Patent Application Publication
(10) Pub. No.: US 2006/0035016 A1
(43) Pub. Date: Feb. 16, 2006

(54) Electroless metal deposition methods

(76) Inventor: Chandra Tiwari, Boise, ID (US)

Correspondence Address: WELLS ST. JOHN P.S., 601 W. FIRST AVENUE, SUITE 1300, SPOKANE, WA, 99201, US

(21) Appl. No.: 10/916,825

(22) Filed: Aug. 11, 2004

(51) Int. Cl. B05D 3/04; B05D 1/18; H05K 3/00

(52) U.S. Cl. 427/97.9; 427/304; 427/443.1; 427/437

(57) ABSTRACT

An electroless metal deposition method includes pretreating a substrate with a solution including an admixture of an ammonium-based hydroxide and water and removing the solution, without any subsequent additional pretreatment, contacting the substrate with an electroless deposition bath, and depositing a metal layer. The metal may consist of nickel. The bath may exhibit a self-initiation temperature and the pretreating may reduce the self-initiation temperature in comparison to an otherwise identical method lacking the pretreating. Another deposition method includes pretreating a conductive surface of a substrate with a solution exhibiting a second pH greater than a first pH of an electroless deposition bath but no less than 9, contacting the substrate with the bath, and depositing a nickel layer. The substrate may include a conductive surface within an opening having an insulative sidewall surface. The opening may include a contact via such that the conductive surface is within the contact via.

### TECHNICAL FIELD

The invention pertains to electroless metal deposition methods, including nickel deposition.

### BACKGROUND OF THE INVENTION

Electroless deposition constitutes one of many possible metal deposition methods. Electroless deposition is of interest in semiconductor fabrication and other technologies. Electroless deposition has a variety of applications in semiconductor manufacturing alone. For example, electroless deposition may be used to fill vias between metallization levels, form contacts or interconnects, etc. FIG. 1 provides an example of an intermediate semiconductor construction wherein electroless deposition may be used. A substrate 10 shown in FIG. 1 includes a contact 12 formed in an insulation layer 14 and an insulation layer 16 formed over contact 12 and insulation layer 14. A low K barrier 18 is over insulation layer 16 and an insulation layer 20 is over low K barrier 18.

A via 24 extends through insulation layer 20, low K barrier 18, and insulation layer 16 to expose contact 12. Contact 12 is positioned at one metallization level and conductive material formed within via 24 may electrically connect contact 12 with another metallization level at a higher elevation. Via 24 includes a sidewall 28 that may comprise a variety of materials or the same material. For example, in FIG. 1, insulation layer 16 may include silicon dioxide and insulation layer 20 may include silicon nitride. Nickel constitutes one exemplary fill material for via 24.

Electroless deposition includes a variety of approaches to fill via 24. In conformal deposition, a seed layer containing metal or a metal compound is formed over substrate 10 and metal deposited thereon from an electroless deposition bath. Typically, the seed layer is activated by a heavy metal, such as palladium, in order to activate deposition from the bath. Unfortunately, conformal deposition within via 24 can easily yield voids when, as shown in FIG. 3, deposition of a metal layer 34 on sidewall 28 progressively narrows the opening of via 24 until it pinches off, producing a void 36 prior to complete filling of via 24.

In another method, called bottom-up deposition, selective activation of the exposed portion of contact 12 at the bottom of via 24 is attempted followed by metal deposition on all activated surfaces from an electroless deposition bath. Conventional selective activation chemistry has demonstrated activation of undesired portions of substrates. For example, as shown in FIG. 2, during formation of metal fill 22 extraneous metal 30 forms at the opening of via 24, blocking continued deposition and creating a void 32. Accordingly, a desire exists for electroless deposition methods that eliminate formation of voids by pinching off via openings such as shown in FIGS. 2 and 3.

### SUMMARY OF THE INVENTION

According to one aspect of the invention, an electroless metal deposition method includes providing a substrate, providing an electroless deposition bath containing metal, and pretreating the substrate with a solution consisting of or consisting essentially of an admixture of an ammonium-based hydroxide and water and removing the solution from at least a portion of the substrate. The method includes, without any subsequent additional pretreatment, contacting the substrate with the bath and electrolessly depositing on the substrate a layer containing metal from the bath. As an example, the metal may consist of nickel. The substrate may include a first surface and a second surface. The depositing may occur selective to the first surface. The first surface may consist of or consist essentially of copper and/or tungsten. Also, the second surface may be insulative. The electroless deposition bath may exhibit a self-initiation temperature and the pretreating may reduce the self-initiation temperature in comparison to an otherwise identical method lacking the pretreating. Removing the solution may include rinsing the substrate with deionized water. Instead, removing the solution may include evaporating the solution.

According to another aspect of the invention, an electroless nickel deposition method includes providing a substrate including a conductive surface, providing an electroless deposition bath containing nickel and exhibiting a first pH, and pretreating at least the conductive surface with a solution exhibiting a second pH greater than the first pH but no less than 9. The method includes contacting the substrate with the bath and electrolessly depositing on the conductive surface a layer containing nickel from the bath.

According to a further aspect of the invention, an electroless nickel deposition method includes providing a substrate including a conductive surface within an opening having an insulative sidewall surface, providing a self-initiating electroless deposition bath containing nickel and exhibiting a first pH and a self-initiation temperature, and pretreating the conductive surface and the insulative surface with a solution exhibiting a second pH greater than the first pH but no less than 9. The method includes removing the solution from the substrate but leaving a part of the solution within the opening in contact with the conductive surface and subsequently contacting the part of the solution and the substrate with the bath. Electroless deposition occurs on the conductive surface to form a layer containing nickel from the bath. The pretreating reduces the self-initiation temperature in comparison to an otherwise identical method lacking the pretreating. The depositing may occur selective to the conductive surface. The opening in the substrate having an insulative sidewall surface may include a contact via such that the conductive surface is within the contact via.

According to a still further aspect of the invention, an electroless nickel deposition method includes providing a substrate including a conductive surface within an opening having an insulative sidewall surface, providing a self-initiating, electroless deposition bath containing nickel, and exhibiting a first pH and a self-initiation temperature, and pretreating the conductive surface and the insulative surface with a solution consisting of an admixture of a hydroxide compound and solvent and exhibiting a second pH greater than the first pH but no less than 9. The method includes removing the solution from the substrate but leaving a part of the solution within the opening in contact with the conductive surface and, without any subsequent additional pretreatment, subsequently contacting the part of the solution and the conductive surface to the deposition bath. The method includes electrolessly depositing on the conductive surface a layer consisting of nickel from the bath. The pretreating reduces the self-initiation temperature in comparison to an otherwise identical method lacking the pretreating and the depositing occurs selective to the conductive surface.

### BRIEF DESCRIPTION OF THE DRAWINGS

Preferred embodiments of the invention are described below with reference to the following accompanying drawings.

FIG. 1 is a partial sectional view of a substrate at a process step according to an aspect of the invention.

FIG. 2 is a partial sectional view of the FIG. 1 substrate at a subsequent process step according to conventional bottom-up deposition methods.

FIG. 3 is a partial sectional view of the FIG. 1 substrate at a subsequent process step according to conventional conformal deposition methods.

FIG. 4 is a partial sectional view of the FIG. 1 substrate at a subsequent process step according to an aspect of the invention.

FIG. 5 is a micrograph from a scanning electron microscope (SEM) of a structure formed by a method according to an aspect of the invention.

FIG. 6 shows a diagrammatic view of computer illustrating an exemplary application of the present invention.

FIG. 7 is a block diagram showing particular features of the motherboard of the FIG. 6 computer.

FIG. 8 shows a high level block diagram of an electronic system according to an exemplary aspect of the present invention.

FIG. 9 shows a simplified block diagram of an exemplary device according to an aspect of the present invention.

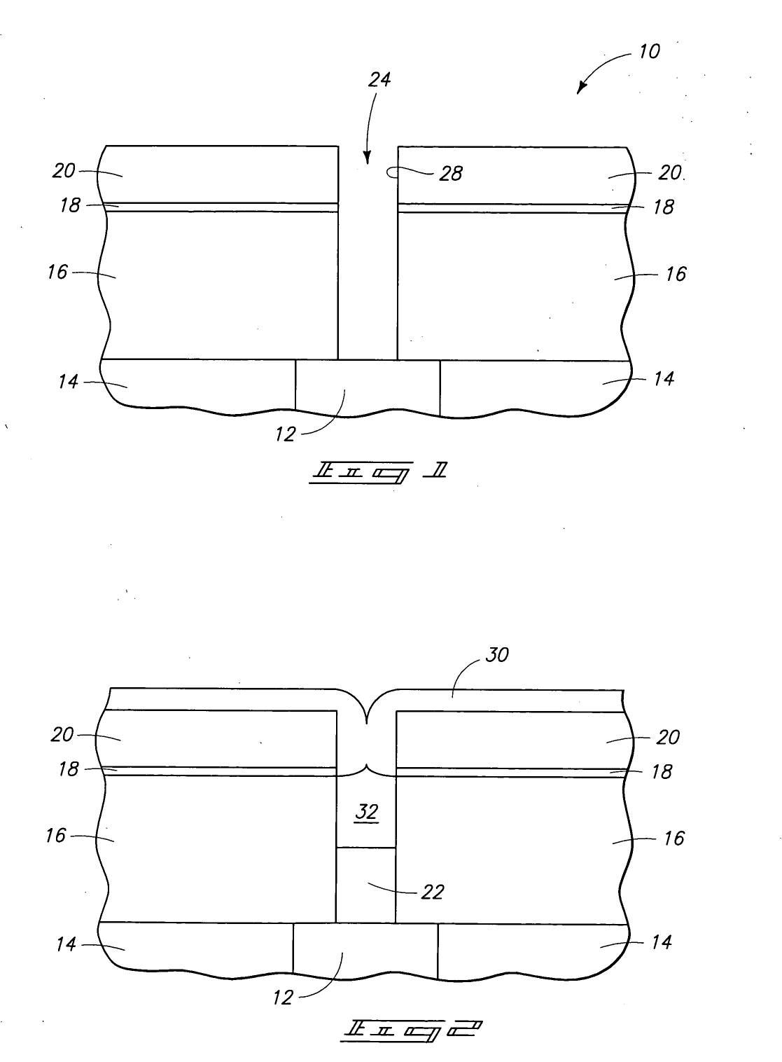

### DETAILED DESCRIPTION OF THE PREFERRED EMBODIMENTS

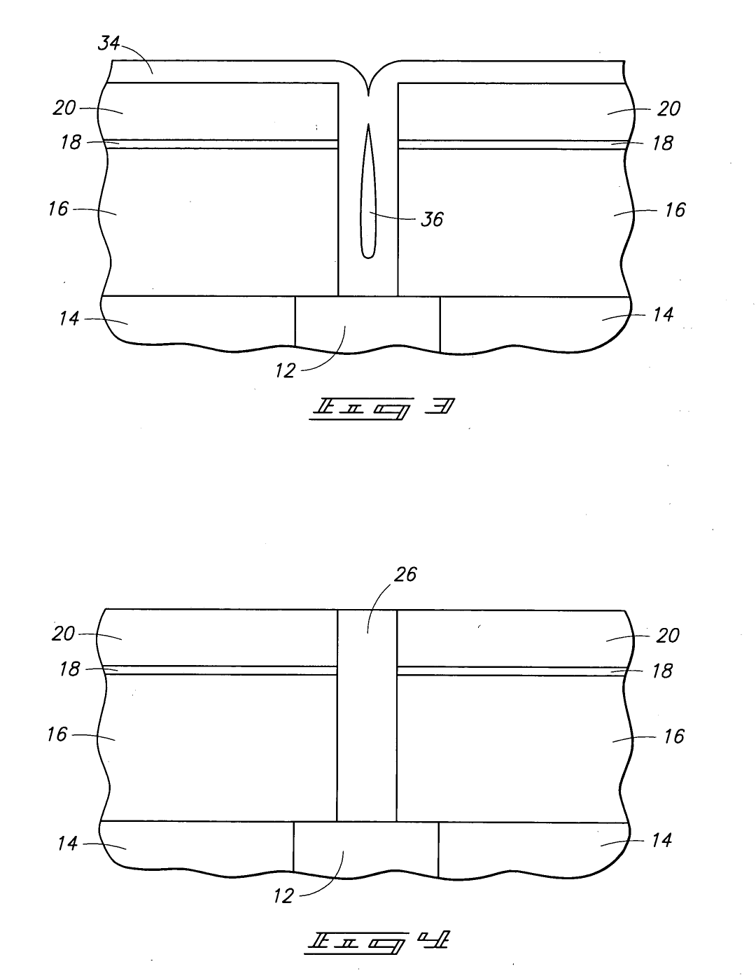

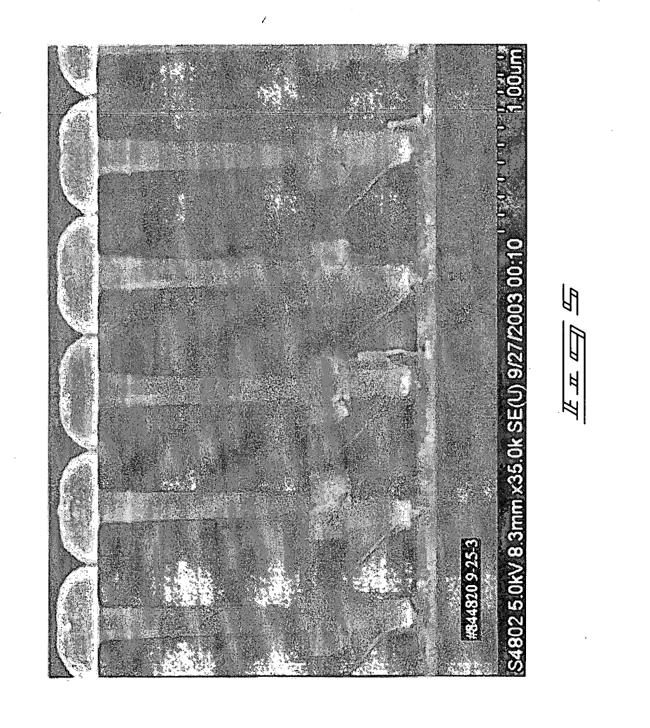

Observation indicated that activation chemistries including PdCl₂/HF, PdSO₄/HF, etc. used in bottom-up nickel deposition unintentionally activate silicon nitride and some low K barrier material in addition to contacts that contain tungsten or copper. Turning to FIG. 2, when insulation layer 20 contains silicon nitride, the observed extraneous activation may form extraneous metal 30 resulting in void 32. One exemplary low K barrier material suffering this problem includes BLOk (TM) containing 46.7 atomic percent (at %) Si, 33 at % C, 18.8 at % N, and 1.5 at % 0 deposited by a method developed by Applied Materials of Santa Clara, Calif. Attempts to conduct electroless nickel deposition with different activation chemistries, such as PdCl₂/H₂SO₄, PdSO₄/H₂SO₄, and PdCl₂/HCl, did not alleviate the problem.

Accordingly, aspects of the invention eliminate the activation step and may achieve selective deposition on copper and tungsten without forming nickel material on silicon nitride and BLOk or other undesired parts of a substrate. A related patent application entitled “Self-Activated Electroless Metal Deposition” filed on Mar. 4, 2004 as U.S. patent application Ser. No. 10/793,990, by the present inventor is incorporated herein by reference for its pertinent and supportive teachings. While such process improves upon electroless metal deposition methods relying upon activation, observations indicated that further improvements may be made.

For deposition on a tungsten substrate, the “activation-free” (synonymous with “self-activated” or “self-initiating”) method operated at a bath temperature of 65 to 66° C. Generally, a deposition bath exhibits a minimum self-initiation temperature. At a lower temperature, self-initiation does not occur or occurs at a rate so slow as to prevent practicable deposition, as known to those of ordinary skill. As temperature increases, the deposition bath becomes less stable. With the decrease in bath stability, deposition begins to occur in the deposition tool on undesired surfaces. Accordingly, a range of suitable operation temperature typically may be designated with a minimum temperature determined by self-initiation temperature and a maximum temperature determined by bath stability. In some circumstances, the range may be only 1 or 2° C.

Bath stability also decreases throughout a deposition process such that, at some point, perhaps after multiple deposition cycles, the bath must be replaced, regenerated or otherwise refreshed to its more stable initial composition. Achieving a lower self-initiation temperature for an electroless deposition bath can improve bath stability since it may allow operation at lower temperatures. Lowering bath temperature may thus improve bath stability and significantly increase the useful life of a given bath. Improved bath stability may reduce deposition on unwanted surfaces in the deposition tool, reduce tool down-time for cleaning, allow processing of more substrates within a given bath, improve repeatability of deposition, and improve uniformity of deposition on a given substrate.

In an attempt to reduce self-initiation temperature, intended deposition substrates, for example copper and/or tungsten contacts, were cleaned prior to electroless nickel deposition. A belief existed that removing native oxide on copper and/or tungsten contacts might assist in lowering self-initiation temperature. “Tungsten ammonia peroxide mixture” (WAPM; a volumetric 1:1:50 admixture of NH₄OH, H₂O₂, and H₂O, respectively with a pH of 10.3) and Q-Etch II (QEII; containing 35-40 weight percent (wt %) NH₄F, 5 wt % H₃PO₃, and 55-60 wt % H₂O with a pH of 7.0) were applied to copper and tungsten substrates and evaluation failed to indicate a desired improvement. Specifically, WAPM increased self-initiation temperature for both copper and tungsten substrates. Also, QEII lowered self-initiation temperature for tungsten substrates by only 2 to 3° C. and did not affect copper substrates. Unfortunately, even though self-initiation temperature decreased slightly with QEII cleaning, bath stability at the slightly lowered temperature was not satisfactory.

According to one aspect of the invention, an electroless metal deposition method includes providing a substrate, providing an electroless deposition bath containing metal, and pretreating the substrate with a solution consisting of or consisting essentially of an admixture of an ammonium-based hydroxide and water and removing the solution from at least a portion of the substrate. The method includes, without any subsequent additional pretreatment, contacting the substrate with the bath and electrolessly depositing on the substrate a layer containing metal from the bath. As an example, the metal may consist of nickel. Given the variety of electroless deposition baths encompassed by the present method, the layer may include other metals, however, the layer may consist of or consist essentially of nickel. Other metals of particular interest include copper, cobalt, gold, and palladium.

The substrate may include a first surface and a second surface. The depositing may occur selective to the first surface. The first surface may consist of or consist essentially of copper and/or tungsten. Also, the second surface may be insulative. The substrate may include an integrated circuit contact. The integrated circuit contact may be comprised by a memory device. The layer may be deposited on the contact and the method may further include forming a metal interconnect using the layer.

In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

The aspects of the invention may have broad applicability to a variety of electroless metal deposition methods. However, pretreating a substrate with a solution in the various manners described herein is particularly applicable to methods using an electroless nickel deposition bath that is self-initiating. A “self-initiating” bath exhibits the property of initiating electroless deposition without the commonly relied upon step of first activating a substrate. Unless indicated otherwise, the methods described herein may include activation of a substrate prior to conducting electroless deposition. However, the self-initiating, electroless deposition bath described in U.S. patent application Ser. No. 10/793,990 mentioned above and any other known self-initiating, electroless deposition baths included in the scope of the aspects of the invention described herein may effectively electrolessly deposit without relying upon activation of the substrate.

The pretreating may occur at a temperature of from about 20 to about 50° C., or preferably at room temperature and at ambient pressure. Pretreating the substrate may include dipping the substrate in a bath of the solution, spraying the solution on the substrate, or spin applying the solution. When spin applying the solution, about 1 to about 2 milliliters (mL) of solution may be dispensed at the center of the substrate while it is rotating. The spin apply method has proven particularly effective. The substrate may remain in contact with the solution for from about 5 seconds to about 5 minutes, or preferably from about 10 to about 30 seconds.

The electroless deposition bath may exhibit a self-initiation temperature and the pretreating may reduce the self-initiation temperature in comparison to an otherwise identical method lacking the pretreating. The self-initiation temperature may be reduced by at least 4° C. or, preferably, by at least 10° C. Observation of some deposition baths has indicated that a reduction of self-initiation temperature of at least 4° C. can noticeably improve bath stability while reduction of 3° C. or less tends not to yield a statistically significant improvement in bath stability. Improvements in self-initiation temperature of about 13° C. have been observed and improvement approaching, or possibly exceeding, 15° C. are expected with continued optimization of process parameters and bath/solution composition tailored to specific substrate composition.

For example, the electroless deposition bath may exhibit a first pH and the solution may exhibit a second pH greater than the first pH but no less than 9. The solution may be formed from about 29 to about 100 volume percent (vol %) ammonium-based hydroxide and from about 0 to about 71 vol % water. The ammonium-based hydroxide may consist of or consist essentially of ammonium hydroxide (NH₄OH). The term “ammonium-based” thus refers to primary, secondary, tertiary, and quaternary substituted ammonium ions where the hydrogen atoms may be replaced with alkyl moieties. One common suitable example includes tetramethylammonium hydroxide (TMAH). Understandably, a solution consisting of an admixture of an ammonium-based hydroxide and water encompasses multiple different ammonium-based hydroxide compounds, for example, ammonium hydroxide and TMAH. A 37 vol % ammonium hydroxide solution with the remainder water has proven particularly effective.

Removing the solution from at least a portion of the substrate includes a variety of possible methods. Removing the solution may include rinsing the substrate with deionized water. Instead, removing the solution may include evaporating the solution. As will be appreciated from the further discussion of the invention below, rinsing the substrate preferably includes a light rinse. Since ammonium hydroxide evaporates easily, its use may be preferred when the solution removing method includes evaporation.

According to another aspect of the invention, an electroless nickel deposition method includes providing a substrate including a conductive surface, providing an electroless deposition bath containing nickel and exhibiting a first pH, and pretreating at least the conductive surface with a solution exhibiting a second pH greater than the first pH but no less than 9. The method includes contacting the substrate with the bath and electrolessly depositing on the conductive surface a layer containing nickel from the bath. As an example, the substrate may further include an insulative surface and the depositing may occur selective to the conductive surface. The conductive surface may consist of or consist essentially of copper and/or tungsten. The conductive surface may include an integrated circuit contact in a memory device. The solution may consist of or consist essentially of an admixture of an ammonium-based hydroxide and water. As an example, the method may further include removing the solution from at least a portion of the substrate before the electroless deposition.

According to a further aspect of the invention, an electroless nickel deposition method includes providing a substrate including a conductive surface within an opening having an insulative sidewall surface, providing a self-initiating electroless deposition bath containing nickel and exhibiting a first pH and a self-initiation temperature, and pretreating the conductive surface and the insulative surface with a solution exhibiting a second pH greater than the first pH but no less than 9. The method includes removing the solution from the substrate but leaving a part of the solution within the opening in contact with the conductive surface and subsequently contacting the part of the solution and the substrate with the bath. Electroless deposition occurs on the conductive surface to form a layer containing nickel from the bath. The pretreating reduces the self-initiation temperature in comparison to an otherwise identical method lacking the pretreating. The depositing may occur selective to the conductive surface. The opening in the substrate having an insulative sidewall surface may include a contact via such that the conductive surface is within the contact via.

Although the aspects of the invention are applicable to a variety of substrates, they may bear particular utility with regard to deep contact vias or similar deep openings in a substrate having a conductive surface within the opening. Within the context of the present document, the term “deep via” refers to an opening having an aspect ratio of at least about 5:1 (depth:width). As may be appreciated from FIGS. 2 and 3 discussed above, electroless nickel deposition relying upon activation chemistry exhibits difficulties in effectively filling deep vias. The activation-free (or self-initiating) electroless metal deposition method described in U.S. patent application Ser. No. 10/793,990 and perhaps other electroless metal deposition methods resolve some of the difficulties associated with relying upon activation chemistry. However, bath stability remains a process parameter that may be improved upon.

The present aspect of the invention specifically describes removing the pretreating solution from the substrate but leaving a part of the solution within the opening in contact with the conductive surface. The remaining part of the solution and the substrate are subsequently contacted with the deposition bath. A belief exists based upon observation that the remaining part of the solution in contact with the conductive surface, as well as other incidents of pretreating, may contribute to the effectiveness of the pretreating in reducing self-initiation temperature.

Without being limited to any particular theory, observations showed that dilute sulfuric acid cleaning hindered initiation in contact vias having a copper contact within the deep opening. It appeared that after sulfuric acid cleaning the pH at the via bottom dropped. Since a self-initiating electroless deposition bath can potentially be highly sensitive to pH for nucleation of the deposited layer to start, sulfuric acid cleaning without entirely removing acid residues may have produced delayed/hindered deposition.

Conversely, it was hypothesized that if pH could be made a little higher than the bath pH at a point of layer initiation, then self-initiation might occur at less aggressive process conditions, such as lower temperature. Since a pretreating solution may be removed less readily from the bottom of a deep via in comparison to other parts of a substrate, it presents an ideal location for retaining a sufficient amount of higher pH pretreating solution to locally increase pH of a deposition bath and thus lower self-initiation temperature.

Comparable precleaning processes that merely removed native oxide from conductive contacts did not produce significant reductions in self-initiation temperature. For example, the native oxide cleaning of tungsten with WAPM mentioned above increased self-initiation temperature, apparently due to the negative effect of H₂O₂ in WAPM. Even so, it is believed that the various aspects of the invention described herein may clean native oxide from the substrate as well as increase pH and that such cleaning may function in conjunction with the pH increase to decrease self-initiation temperature. Accordingly, pretreating solutions that merely increase pH without cleaning native oxide might not exhibit the same effectiveness in lowering self-initiation temperature. Also, some pretreating solutions with a pH no less than 9 (such as WAPM) that also clean native oxide nevertheless might not exhibit the same effectiveness due to counterproductive constituents (such as H₂O₂).

According to a still further aspect of the invention, an electroless nickel deposition method includes providing a substrate including a conductive surface within an opening having an insulative sidewall surface, providing a self-initiating, electroless deposition bath containing nickel, and exhibiting a first pH and a self-initiation temperature, and pretreating the conductive surface and the insulative surface with a solution consisting of an admixture of a hydroxide compound and solvent and exhibiting a second pH greater than the first pH but no less than 9. The method includes removing the solution from the substrate but leaving a part of the solution within the opening in contact with the conductive surface and, without any subsequent additional pretreatment, subsequently contacting the part of the solution and the conductive surface to the deposition bath. The method includes electrolessly depositing on the conductive surface a layer consisting of nickel from the bath.

The pretreating reduces the self-initiation temperature in comparison to an otherwise identical method lacking the pretreating and the depositing occurs selective to the conductive surface. By way of example, the hydroxide compound may consist of or consist essentially of ammonium hydroxide. Alternative hydroxide compounds include potassium hydroxide, sodium hydroxide, etc. The solvent may consist of or consist essentially of water. Other aspects of the invention described herein may also use the alternative hydroxide compounds.

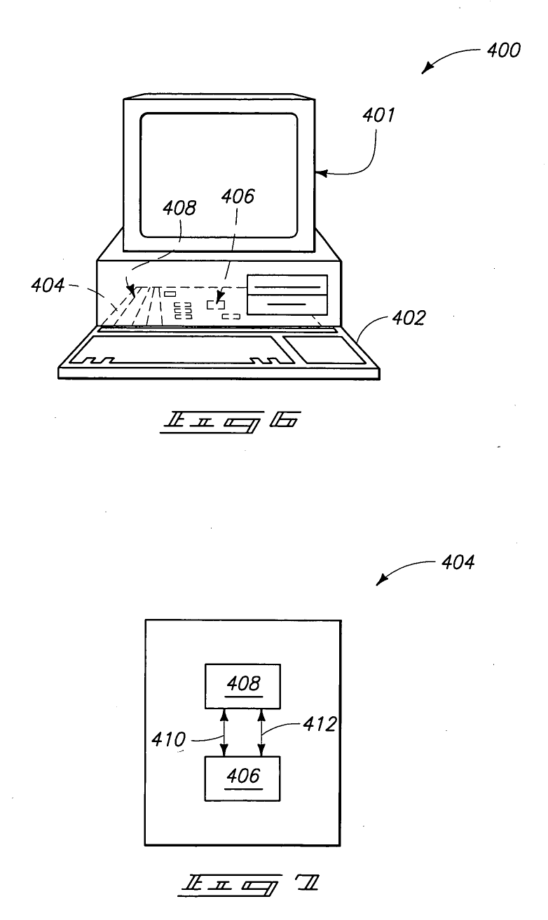

The method aspects of the inventions may be used in forming a variety of devices. FIG. 6 illustrates generally, by way of example, but not by way of limitation, an embodiment of a computer system 400 according to an aspect of the present invention. Computer system 400 includes a monitor 401 or other communication output device, a keyboard 402 or other communication input device, and a motherboard 404. Motherboard 404 can carry a microprocessor 406 or other data processing unit, and at least one memory device 408. Memory device 408 can comprise various aspects of the invention described above. Memory device 408 can comprise an array of memory cells, and such array can be coupled with addressing circuitry for accessing individual memory cells in the array. Further, the memory cell array can be coupled to a read circuit for reading data from the memory cells. The addressing and read circuitry can be utilized for conveying information between memory device 408 and processor 406. Such is illustrated in the block diagram of the motherboard 404 shown in FIG. 7. In such block diagram, the addressing circuitry is illustrated as 410 and the read circuitry is illustrated as 412.

In particular aspects of the invention, memory device 408 can correspond to a memory module. For example, single in-line memory modules (SIMMs) and dual in-line memory modules (DIMMs) may be used in the implementation that utilizes the teachings of the present invention. The memory device can be incorporated into any of a variety of designs that provide different methods of reading from and writing to memory cells of the device. One such method is the page mode operation. Page mode operations in a DRAM are defined by the method of accessing a row of a memory cell arrays and randomly accessing different columns of the array. Data stored at the row and column intersection can be read and output while that column is accessed.

An alternate type of device is the extended data output (EDO) memory that allows data stored at a memory array address to be available as output after the addressed column has been closed. This memory can increase some communication speeds by allowing shorter access signals without reducing the time in which memory output data is available on a memory bus. Other alternative types of devices include SDRAM, DDR SDRAM, SLDRAM, VRAM and Direct RDRAM, as well as others such as SRAM or Flash memories.

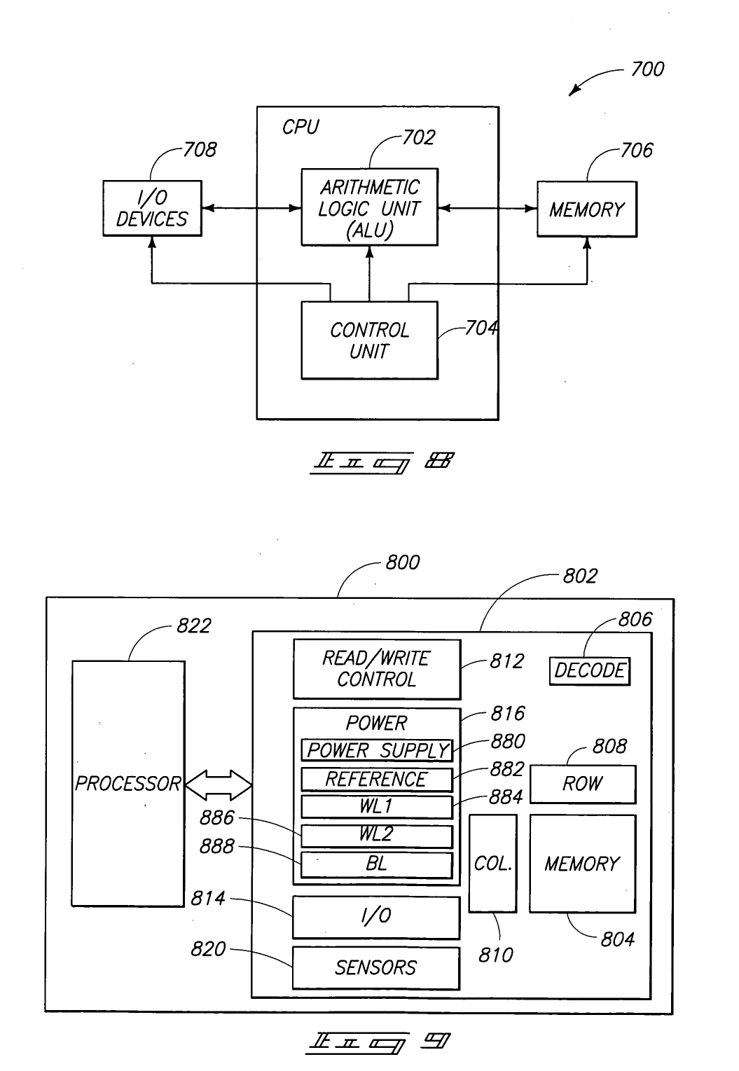

FIG. 8 illustrates a simplified block diagram of a high-level organization of various embodiments of an exemplary electronic system 700 of the present invention. System 700 can correspond to, for example, a computer system, a process control system, or any other system that employs a processor and associated memory. Electronic system 700 has functional elements, including a processor or arithmetic/logic unit (ALU) 702, a control unit 704, a memory device unit 706 and an input/output (I/O) device 708. Generally, electronic system 700 will have a native set of instructions that specify operations to be performed on data by the processor 702 and other interactions between the processor 702, the memory device unit 706 and the I/O devices 708. The control unit 704 coordinates all operations of the processor 702, the memory device 706 and the I/O devices 708 by continuously cycling through a set of operations that cause instructions to be fetched from the memory device 706 and executed. In various embodiments, the memory device 706 includes, but is not limited to, random access memory (RAM) devices, read-only memory (ROM) devices, and peripheral devices such as a floppy disk drive and a compact disk CD-ROM drive. One of ordinary skill in the art will understand, upon reading and comprehending this disclosure, that any of the illustrated electrical components are capable of being fabricated to include DRAM cells in accordance with various aspects of the present invention.

FIG. 9 is a simplified block diagram of a high-level organization of various embodiments of an exemplary electronic system 800. The system 800 includes a memory device 802 that has an array of memory cells 804, address decoder 806, row access circuitry 808, column access circuitry 810, read/write control circuitry 812 for controlling operations, and input/output circuitry 814. The memory device 802 further includes power circuitry 816, and sensors 820, such as current sensors for determining whether a memory cell is in a low-threshold conducting state or in a high-threshold non-conducting state. The illustrated power circuitry 816 includes power supply circuitry 880, circuitry 882 for providing a reference voltage, circuitry 884 for providing the first wordline with pulses, circuitry 886 for providing the second wordline with pulses, and circuitry 888 for providing the bitline with pulses. The system 800 also includes a processor 822, or memory controller for memory accessing.

The memory device 802 receives control signals 824 from the processor 822 over wiring or metallization lines. The memory device 802 is used to store data that is accessed via I/O lines. It will be appreciated by those skilled in the art that additional circuitry and control signals can be provided, and that the memory device 802 has been simplified to help focus on the invention. At least one of the processor 822 or memory device 802 can include a capacitor construction in a memory device of the type described previously herein.

The various illustrated systems of this disclosure are intended to provide a general understanding of various applications for the circuitry and structures of the present invention, and are not intended to serve as a complete description of all the elements and features of an electronic system using memory cells in accordance with aspects of the present invention. One of the ordinary skill in the art will understand that the various electronic systems can be fabricated in single-package processing units, or even on a single semiconductor chip, in order to reduce the communication time between the processor and the memory device(s).

Applications for memory cells can include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

### EXAMPLE 1

A contact via to a copper contact on a silicon wafer piece (3 centimeters×2 centimeters) was formed through a 0.2 micrometer (μm) layer of silicon nitride, a 20 nanometer (nm) layer of BLOk (TM), and a 1.0 μm layer of silicon dioxide. The contact via had a depth of 1.220 μm and diameter of 0.18 μm to provide an aspect ratio of 6.8. About 2 mL of 37 vol % ammonium hydroxide aqueous solution was dispensed at the center of the silicon wafer piece. After a delay to allow evaporation of the pretreating solution based upon visual inspection, electroless nickel deposition in a bath occurred at an initiation temperature of 52° C. The bath contained 5 vol % XP-3306 R nickel sulfate solution, 10 vol % XP-3306 M-0 make-up solution containing an organic salt, 10 vol % XP-3306 S-0 reducing agent solution containing dimethylaminoborane (DMAB), and 0.4 vol % XP-3307 stabilizer with the remainder water plus sufficient ammonium hydroxide to adjust pH to 8.25. All of the XP solutions are of proprietary composition and are available from Rohm and Haas Electronic Materials in Marlborough, Mass. Bottom-up deposition proceeded until a void-free nickel fill was formed within the contact via. FIG. 5 shows the resulting nickel fill.

### EXAMPLE 2

The method described in Example 1 was performed without pretreatment and exhibited an initiation temperature of 65° C. Comparison of the Examples 1 and 2 substrates did not reveal apparent damage to the Example 1 dielectric materials by the ammonium hydroxide pretreatment.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

I claim:

1. An electroless metal deposition method comprising:
providing a substrate;
providing an electroless deposition bath containing metal;
pretreating the substrate with a solution consisting of an admixture of an ammonium-based hydroxide and water and removing the solution from at least a portion of the substrate; and
without any subsequent additional pretreatment, contacting the substrate with the bath and electrolessly depositing on the substrate a layer containing metal from the bath.

2. The method of claim 1 wherein the metal consists of nickel.

3. The method of claim 1 wherein the substrate comprises a first surface and a second surface and the depositing occurs selective to the first surface.

4. The method of claim 3 wherein the first surface consists of copper and/or tungsten and the second surface is insulative.

5. The method of claim 1 wherein the substrate comprises a bulk semiconductive wafer.

6. The method of claim 1 wherein the substrate comprises an integrated circuit contact, the layer is deposited on the contact, and the method further comprises forming a metal interconnect using the layer.

7. The method of claim 6 wherein the integrated circuit contact is comprised by a memory device.

8. The method of claim 1 wherein the electroless deposition bath is self-initiating.

9. The method of claim 1 wherein the electroless deposition bath exhibits a self-initiation temperature and the pretreating reduces the self-initiation temperature in comparison to an otherwise identical method lacking the pretreating.

10. The method of claim 9 wherein the self-initiation temperature is reduced by at least 4° C.

11. The method of claim 10 wherein the self-initiation temperature is reduced by at least 10° C.

12. The method of claim 1 wherein the electroless deposition bath exhibits a first pH and the solution exhibits a second pH greater than the first pH but no less than 9.

13. The method of claim 1 wherein the solution is formed from about 29 to about 100 volume percent (vol %) ammonium-based hydroxide and from about 0 to about 71 vol % water.

14. The method of claim 1 wherein the ammonium-based hydroxide consists of ammonium hydroxide.

15. The method of claim 1 wherein removing the solution comprises rinsing the substrate with deionized water.

16. The method of claim 1 wherein removing the solution comprises evaporating the solution.

17. The method of claim 1 wherein the layer consists of nickel.

18. An electroless nickel deposition method comprising:
providing a substrate including a conductive surface;
providing an electroless deposition bath containing nickel and exhibiting a first pH;
pretreating at least the conductive surface with a solution exhibiting a second pH greater than the first pH but no less than 9; and
contacting the substrate with the bath and electrolessly depositing on the conductive surface a layer containing nickel from the bath.

19. The method of claim 18 wherein the substrate further comprises an insulative surface and the depositing occurs selective to the conductive surface.

20. The method of claim 19 wherein the conductive surface consists of copper and/or tungsten.

21. The method of claim 18 wherein the substrate comprises a bulk semiconductive wafer.

22. The method of claim 18 wherein the conductive surface comprises an integrated circuit contact in a memory device.

23. The method of claim 18 wherein the electroless deposition bath is self-initiating.

24. The method of claim 18 wherein the electroless deposition bath exhibits a self-initiation temperature and the pretreating reduces the self-initiation temperature in comparison to an otherwise identical method lacking the pretreating.

25. The method of claim 24 wherein the self-initiation temperature is reduced by at least 4° C.

26. The method of claim 25 wherein the self-initiation temperature is reduced by at least 10° C.

27. The method of claim 18 wherein the electroless deposition bath exhibits a first pH and the solution exhibits a second pH greater than the first pH but no less than 9.

28. The method of claim 18 wherein the solution is formed from about 29 to about 100 volume percent (vol %) ammonium-based hydroxide and from about 0 to about 71 vol % water.

29. The method of claim 18 wherein the solution consists of an admixture of an ammonium-based hydroxide and water.

30. The method of claim 18 further comprising removing the solution from at least a portion of the substrate before the depositing by rinsing the substrate with deionized water.

31. The method of claim 18 further comprising removing the solution from at least a portion of the substrate before the depositing by evaporating the solution.

32. The method of claim 18 wherein the layer consists of nickel.

33. An electroless nickel deposition method comprising:
providing a substrate including a conductive surface within an opening having an insulative sidewall surface;
providing a self-initiating, electroless deposition bath containing nickel and exhibiting a first pH and a self-initiation temperature;
pretreating the conductive surface and the insulative surface with a solution exhibiting a second pH greater than the first pH but no less than 9;
removing the solution from the substrate but leaving a part of the solution within the opening in contact with the conductive surface and subsequently contacting the part of the solution and the substrate with the bath; and
electrolessly depositing on the conductive surface a layer containing nickel from the bath, the pretreating reducing the self-initiation temperature in comparison to an otherwise identical method lacking the pretreating.

34. The method of claim 33 wherein the depositing occurs selective to the conductive surface.

35. The method of claim 34 wherein the conductive surface consists of copper and/or tungsten.

36. The method of claim 33 wherein the substrate comprises a bulk semiconductive wafer.

37. The method of claim 33 wherein the opening comprises a contact via.

38. The method of claim 33 wherein the conductive surface comprises an integrated circuit contact in a memory device.

39. The method of claim 33 wherein the self-initiation temperature is reduced by at least 4° C.

40. The method of claim 39 wherein the self-initiation temperature is reduced by at least 10° C.

41. The method of claim 33 wherein the solution consists of an admixture of from about 29 to about 100 volume percent (vol %) ammonium-based hydroxide and from about 0 to about 71 vol % water.

42. The method of claim 41 wherein the ammonium-based hydroxide consists of ammonium hydroxide.

43. The method of claim 33 wherein removing the solution comprises rinsing the substrate with deionized water.

44. The method of claim 33 wherein removing the solution comprises evaporating the solution.

45. The method of claim 33 wherein the layer consists of nickel.

46. An electroless nickel deposition method comprising:
providing a substrate including a conductive surface within an opening having an insulative sidewall surface;
providing a self-initiating, electroless deposition bath containing nickel and exhibiting a first pH and a self-initiation temperature;
pretreating the conductive surface and the insulative surface with a solution consisting of an admixture of a hydroxide compound and solvent and exhibiting a second pH greater than the first pH but no less than 9;
removing the solution from the substrate but leaving a part of the solution within the opening in contact with the conductive surface and, without any subsequent additional pretreatment, subsequently contacting the part of the solution and the conductive surface with the bath; and
electrolessly depositing on the conductive surface a layer consisting of nickel from the bath, the pretreating reducing the self-initiation temperature in comparison to an otherwise identical method lacking the pretreating and the depositing occurring selective to the conductive surface.

47. The method of claim 46 wherein the conductive surface consists of copper and/or tungsten.

48. The method of claim 46 wherein the substrate comprises a bulk semiconductive wafer.

49. The method of claim 46 wherein the opening comprises a contact via.

50. The method of claim 46 wherein the conductive surface comprises an integrated circuit contact in a memory device.

51. The method of claim 46 wherein the self-initiation temperature is reduced by at least 4° C.

52. The method of claim 51 wherein the self-initiation temperature is reduced by at least 10° C.

53. The method of claim 46 wherein the solution is formed from about 29 to about 100 volume percent (vol %) ammonium-based hydroxide and from about 0 to about 71 vol % water.

54. The method of claim 46 wherein the hydroxide compound consists of ammonium hydroxide.

55. The method of claim 46 wherein the solvent consists of water.

56. The method of claim 46 wherein removing the solution comprises rinsing the substrate with deionized water.

57. The method of claim 46 wherein removing the solution comprises evaporating the solution.
